(19) United States
(12) Patent Application Publication
(10) Pub. No.: US 2024/0106404 A1
(43) Pub. Date: Mar. 28, 2024

(54) Circuit for Integrating Currents from High-Density Sensors

(71) Applicant: Texas Instruments Incorporated, Dallas, TX (US)

(72) Inventors: Nagesh Surendranath, Frisco, TX (US); Eduardo Bartolome, Dallas, TX (US); Saugata Datta, Kolkata (IN)

(21) Appl. No.: 17/955,503

(22) Filed: Sep. 28, 2022

(51) Int. Cl. H03G 1/04; H03F 1/26; H03F 3/45; H03G 3/30

(52) U.S. Cl. CPC H03G 1/04; H03F 1/26; H03F 3/45475; H03G 3/3031

(57) ABSTRACT

A circuit includes a plurality of first stage integrators. Each of the plurality of first stage integrators includes a first input, a second input, a third input and an output. The first input of each of the plurality of first stage integrators is coupled to a different one of circuit inputs, the second input is coupled to a first reference input, the third input is coupled to a second reference input and the output of each of the plurality of first stage integrators is coupled to the first input of such first stage integrator. The circuit includes a second stage integrator which includes a first input coupled to each of the first inputs of the plurality of first stage integrators, a second input coupled to the first reference input, and an output coupled to the first input of the second stage integrator.

### TECHNICAL FIELD

This description relates generally to circuits for integrating currents from sensors.

### BACKGROUND

Image sensors are used for the conversion of optical image information to electrical signals. Image sensors generate electrical currents according to an amount of light incident on the sensors. Image sensors are used in, for example, electronic imaging devices, medical imaging devices and thermal imaging devices.

Optical nanopore sensors are used in the detection and characterization of clinical biomarkers and for DNA/RNA sequencing. Optical nanopore sensors generally operate by detecting changes in the ionic current through a nanopore.

A sensor system may include hundreds or even thousands of individual sensors (e.g., sensor elements). The individual sensors may be arranged, for example, in a two-dimensional array. Each sensor is typically coupled to an electronic processing circuit via a conductor (e.g., signal trace, channel, wire). The electronic processing circuit converts the electrical current produced by the sensor into a voltage. The electronic processing circuit may include an amplifier which integrates the current and provides an output voltage representing the current. A drawback of many amplifiers is that noise signals (e.g., flicker noise signals or thermal noise signals) that may be present at an input of an amplifier may be amplified and produced at an output of the amplifier. Also, parasitic capacitances of the sensor and the signal trace increase the noise signals.

As noise signals increase, a signal-to-noise ratio (SNR) of an amplifier degrades. To reduce noise signals and increase the SNR, a precision amplifier may be used to convert an electrical current into a voltage. A precision amplifier typically has a large bandwidth, a high gain and a low noise and is typically implemented with multiple gain stages each having several transistors. Thus, a precision amplifier requires a relatively large area to implement in an integrated circuit or a semiconductor die and draws higher current. Because a sensor system may include several thousand sensors which are densely fabricated in an integrated circuit or a semiconductor die and the individual sensors may be coupled to respective precision amplifiers, a high-density sensor system can take a relatively large area in an integrated circuit or in a semiconductor die and can draw higher current which increases power consumption.

### SUMMARY

In one aspect, a circuit includes a plurality of circuit inputs. At least one of the plurality of circuit inputs is adapted to receive an input current. The circuit includes a first reference input adapted to receive a first reference voltage and includes a second reference input adapted to receive a second reference voltage. The circuit includes a plurality of first stage integrators. Each of the plurality of first stage integrators includes a first input, a second input, a third input and an output. The first input of each of the plurality of first stage integrators is coupled to a different one of the circuit inputs, the second input is coupled to the first reference input, the third input is coupled to the second reference input and the output of each of the plurality of first stage integrators is coupled to the first input of such first stage integrator by a first feedback path for such first stage integrator. The circuit includes a second stage integrator which includes a first input, a second input and an output. The first input of the second stage integrator is coupled to each of the first inputs of the plurality of first stage integrators, the second input of the second stage integrator is coupled to the first reference input, and the output of the second stage integrator is coupled to the first input of the second stage integrator by a second feedback path.

In an additional aspect, the circuit includes a plurality of transfer switches. Each of the plurality of transfer switches includes a first terminal and a second terminal. The first terminal of each of the plurality of transfer switches is coupled to a different one of the first inputs of the plurality of first stage integrators and the second terminal of each of the plurality of transfer switches is coupled to the first input of the second stage integrator.

In an additional aspect, the first feedback path of each of the plurality of first stage integrators includes a first switch which includes a first terminal coupled to the output of such first stage integrator and includes a second terminal. The first feedback path of each of the plurality of first stage integrators includes a first feedback capacitor which includes a first terminal coupled to the first input of such first stage integrator and a second terminal coupled to the second terminal of the first switch.

In an additional aspect, each of the plurality of first stage integrators further includes a second switch which includes a first terminal coupled to the second terminal of the first feedback capacitor of such first stage integrator and a second terminal adapted to receive the second reference voltage.

In an additional aspect, a circuit includes a circuit input adapted to receive an input current, a first reference input adapted to receive a first reference voltage and a second reference input adapted to receive a second reference voltage. The circuit includes a first stage integrator which includes a first input coupled to the circuit input, a second input coupled to the first reference input, a third input coupled to the second reference input and an output coupled to the first input of the first stage integrator by a first feedback path. The circuit includes a transfer switch which includes a first terminal coupled to the first input of the first stage integrator and includes a second terminal. The circuit includes a second stage integrator which includes a first input coupled to the second terminal of the transfer switch, a second input coupled to the first reference input, and an output coupled to the first input of the second stage integrator by a third feedback path.

In an additional aspect, a circuit includes a circuit input adapted to receive an input current, a first reference input adapted to receive a first reference voltage and a second reference input adapted to receive a second reference voltage. The circuit includes a first amplifier which includes a first input coupled to the circuit input, a second input coupled to the first reference input and includes an output. The circuit includes a first switch which includes a first terminal coupled to the output of the first amplifier and includes a second terminal. The circuit includes a first feedback capacitor which includes a first terminal coupled to the first input of the first amplifier and a second terminal coupled to the second terminal of the first switch. The circuit includes a second switch which includes a first terminal coupled to the second terminal of the first feedback capacitor and a second terminal coupled to the second reference input. The circuit includes a transfer switch which includes a first terminal coupled to the first input of the first amplifier and includes a second terminal. The circuit includes a second amplifier which includes a first input coupled to the second terminal of the transfer switch, a second input coupled to the first reference input and includes an output. The circuit includes a second feedback capacitor which includes a first terminal coupled to the first input of the second amplifier and a second terminal coupled to the output of the second amplifier.

### BRIEF DESCRIPTION OF THE DRAWINGS

FIG. 1 is a block diagram illustrating a sensor system of an example embodiment.

FIG. 2 is a block diagram illustrating a plurality of sensors coupled to respective first stage integrators which are coupled to a second stage integrator.

FIGS. 3A, 3B and 3C are schematic diagrams illustrating a circuit of an example embodiment.

FIG. 4 is a timing diagram illustrating timing signals and voltages in the circuit of FIGS. 3A-3C.

The same reference numerals or other reference designators are used in the drawings to designate the same or similar (functionally and/or structurally) features.

### DETAILED DESCRIPTION

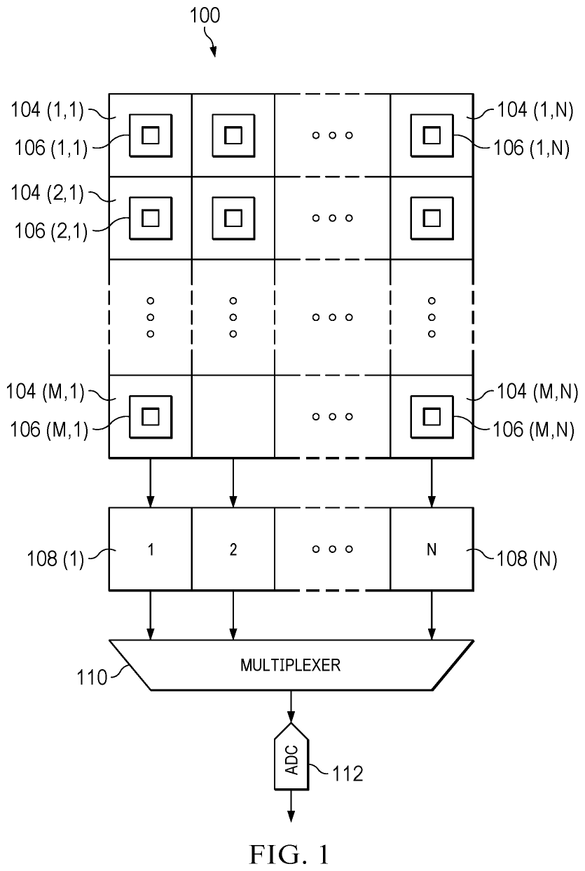

FIG. 1 is a block diagram illustrating system 100 of an example embodiment. System 100 includes a plurality of sensors 104 (1,1)-104 (M,N) that are arranged in a two-dimensional array consisting of M rows and N columns. Sensor 104 (1,1) refers to a sensor in row number 1 and column number 1, and sensor 104 (M,N) refers to a sensor in row number M and column number N. The sensors may, for example, be photodiodes, nanopores or other type of sensors. The sensors may be used in electronic imaging devices, medical imaging devices, thermal imaging devices, and/or in systems for detection and/or characterization of clinical biomarkers and DNA/RNA sequencing.

When energy (e.g., light) is incident on sensors 104 (1,1)-104 (M,N), they generate electrical charge according to the amount of incident energy. In some example embodiments, sensors 104 (1,1)-104 (M,N) are coupled to respective first stage integrators 106 (1,1)-106 (M,N), which may be incorporated with the corresponding sensor (as shown in FIG. 1). Thus, each sensor may be coupled to a corresponding first stage integrator. The charges generated by each sensor is integrated by the corresponding first stage integrator.

System 100 includes second stage integrators 108 (1)-108 (N). Each second stage integrator may be coupled to a corresponding group (such as a column, as illustrated in FIG. 1, or a row) of first stage integrators. For example, second stage integrator 108 (1) may be coupled to the first stage integrators of column number 1, and second stage integrator 108 (N) may be coupled to the first stage integrators of column number N. The charges integrated by the first stage integrators of column number 1 are transferred to second stage integrator 108 (1), and similarly the charges integrated by the first stage integrators of column number N are transferred to second stage integrator 108 (N). Responsive to the charges transferred by the first stage integrators of column number 1, second stage integrator 108 (1) provides output voltages representing the transferred charges to, for example, one input of multiplexer 110. Similarly, responsive to the charges transferred by the first stage integrators of column N, second stage integrator 108 (N) provides output voltages representing the transferred charges to, for example, another input of multiplexer 110.

In some example embodiments, the output voltages provided by second stage integrators 108 (1)-108 (N) are multiplexed by multiplexer (MUX) 110, and the multiplexed output voltages are provided to analog-to-digital converter (ADC) 112. ADC 112 digitizes the output voltages and provides digital information (e.g., digital codes) representing the output voltages to circuitry (such as a processor, state machine, logic circuitry, memory and or a combination thereof) which may include software. Switching of MUX 110 may be controlled by a processor, logic circuitry and/or control circuitry that may be on the same integrated circuit as MUX 110 or may be external to the integrated circuit.

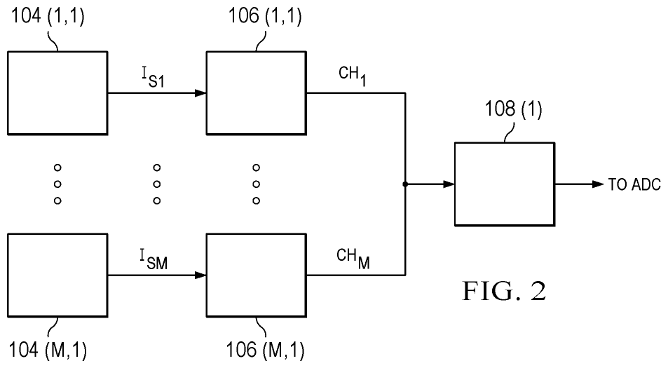

FIG. 2 is a block diagram illustrating sensors 104 (1,1)-104 (M,1) of column number 1 coupled to respective first stage integrators 106 (1,1)-106 (M,1), which are coupled to second stage integrator 108 (1). In response to receiving incident energy (such as light), sensor 104 (1,1) generates input current I_{S1}. First stage integrator 106 (1,1) integrates charges (e.g., charges produced by sensor 104 (1,1) in response to the received incident energy) output by sensor 104 (1,1) in the form of input current I_{S1} and outputs the resulting integrated charges CHI. Similarly, in response to incident energy, sensor 104 (M,1) generates charges which is output as input current I_{SM}. First stage integrator 106 (M,1) integrates the charges output by sensor 104 (M,1) as input current I_{SM} and outputs the resulting integrated charges CH_{M}. Second stage integrator 108 (1) generates output voltages based on the currents/integrated charges provided by first stage integrators 106 (1,1) through 106 (M,1).

In some example embodiments, first stage integrators 106 (1,1)-106 (M,1) integrate charges over respective integration periods and output the resulting integrated charges to second stage integrator 108 (1) over respective transfer periods. The integration periods may be different, or they may overlap in time. The transfer periods may be different, or they may overlap in time. A transfer period may be time delayed from a corresponding integration period to allow adequate time for the integration of charges by a first stage integrator. As described below in more details, the number of transfer periods (may also be referred to as a “transfer phase”) may be any integer value (e.g., 2), and the number of integration periods (may also be referred to as an “integration phase”) may be any integer value (e.g., 2).

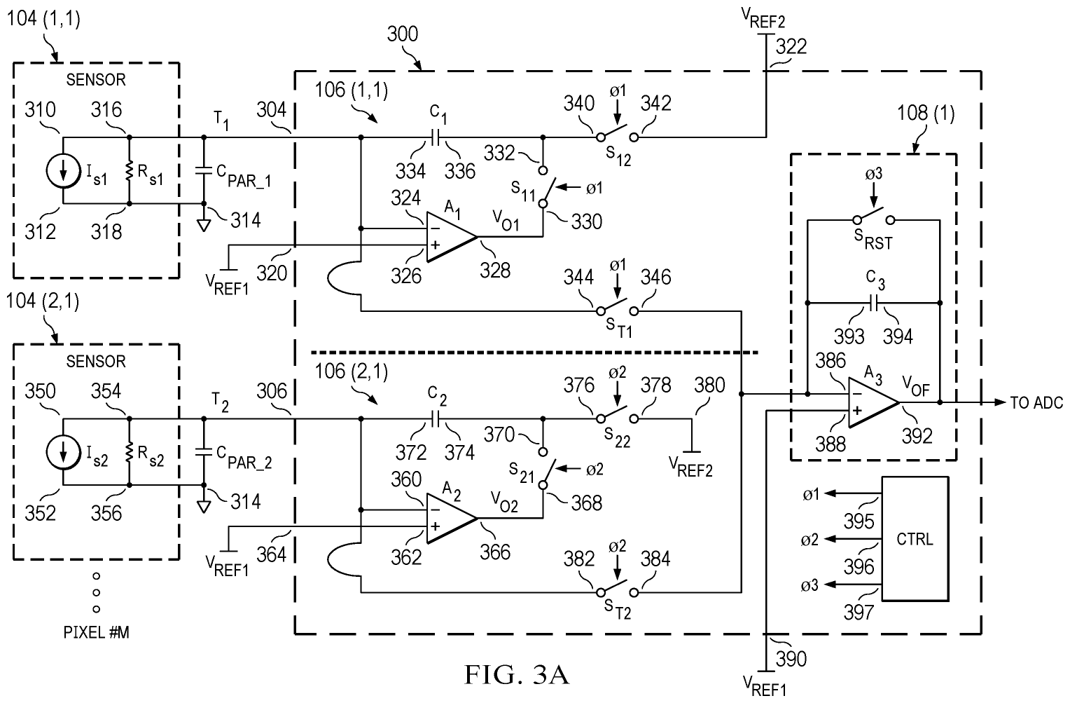

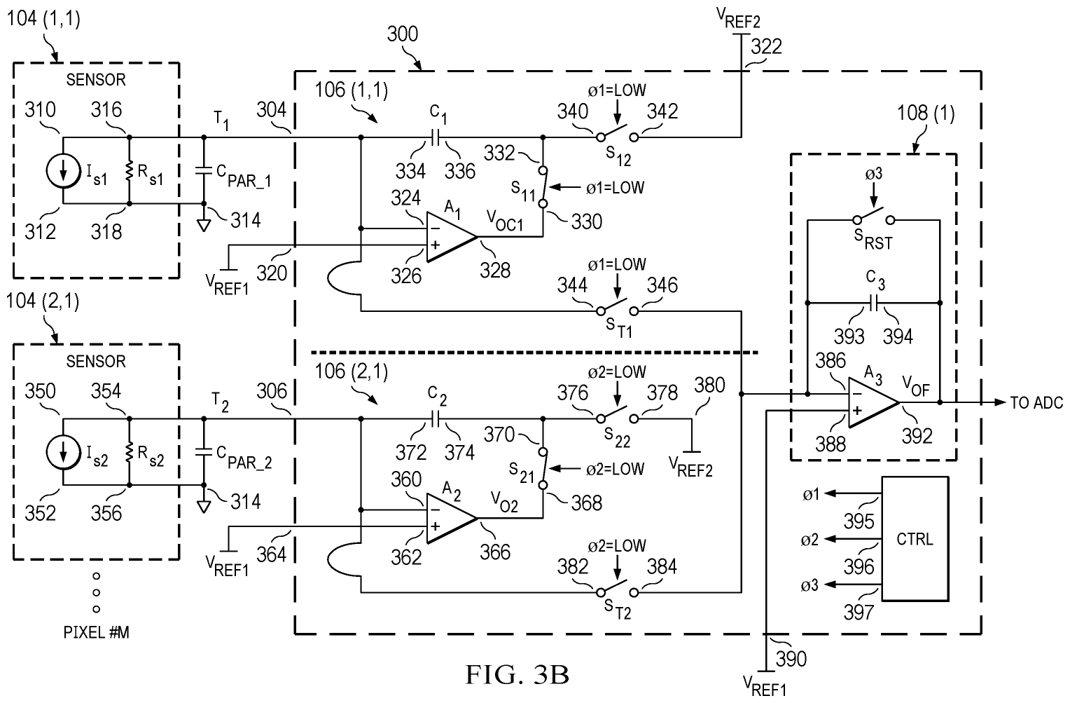

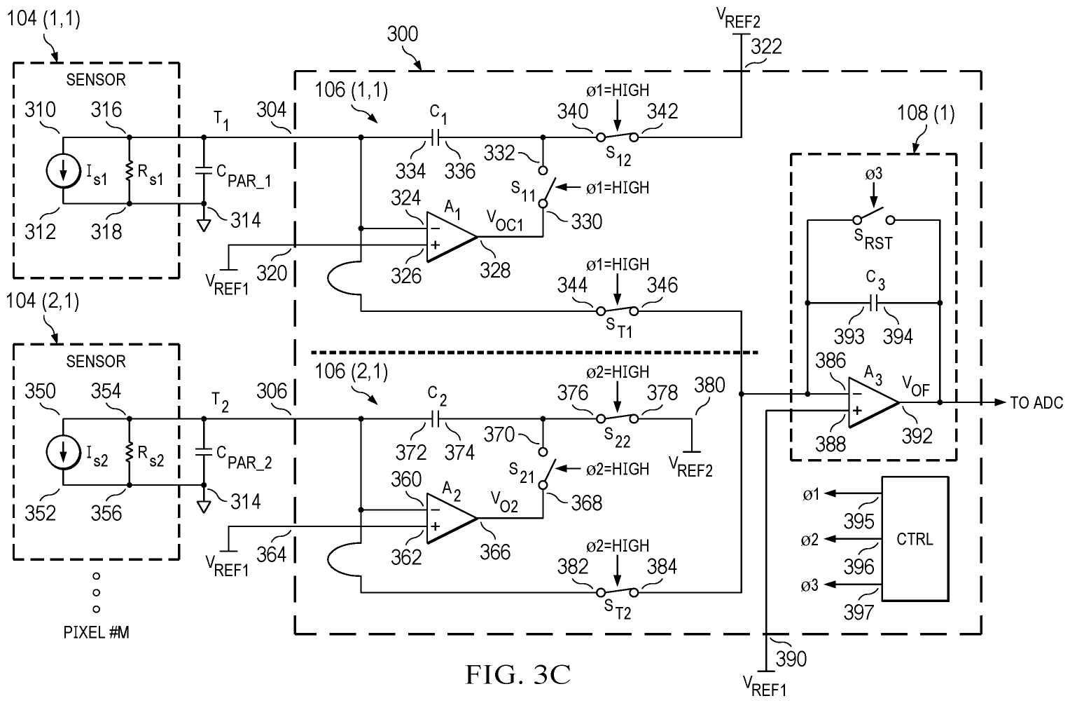

FIG. 3A is a schematic diagram of a circuit 300 of an example embodiment. Circuit 300 includes examples of sensors 104 (1,1) and 104 (2,1), first stage integrators 106 (1,1) and 106 (2,1) and second stage integrator 108 (1). Circuit 300 is configured to receive input currents from a plurality of sensors (e.g., sensors 104 (1,1) and 104 (2,1)) and provide output voltages based on the input currents.

Circuit 300 includes first stage integrator 106 (1,1) coupled to sensor 104 (1,1) and includes first stage integrator 106 (2,1) coupled to sensor 104 (2,1). Circuit 300 includes second stage integrator 108 (1) coupled to first stage integrators 106 (1,1) and 106 (2,1). Circuit 300 includes first circuit input 304 adapted to be coupled to sensor 104 (1,1) and includes second circuit input 306 adapted to be coupled to sensor 104 (2,1).

Sensor 104 (1,1) is modeled by a current source I_{S1} and a parallel resistor R_{S1}, where the current is generated by the charge collected by the energy incident to the sensor. The current source I_{S1} (e.g., between around a few nano-amperes to around a few pico-amperes) includes first terminal 310 coupled to first circuit input 304 and includes second terminal 312 coupled to common potential 314 (e.g., ground). Sensor resistor R_{S1} (e.g., between around 1M ohms to around 1G ohms) includes first terminal 316 coupled to first terminal 310 of I_{S1} and includes second terminal 318 coupled to common potential 314. Sensor 104 (1,1) is coupled to first circuit input 304 via signal trace T₁ (e.g., conductor, wire, channel and/or circuit board trace). Parasitic capacitance C_{PAR_1} may be present between signal trace T₁ and common potential 314. Parasitic capacitance C_{PAR_1} may represent the sum of a sensor parasitic capacitance, a signal trace parasitic capacitance, and any other parasitic capacitance.

Circuit 300 includes first reference input 320 which is adapted to receive first reference voltage V_{REF1} (e.g., around 0V to around 1V) and includes second reference input 322 which is adapted to receive second reference voltage V_{REF2} (e.g., around 0V to around 1.5V).

First stage integrator 106 (1,1) includes first operational amplifier A₁ which includes first input 324 (e.g., inverting input), second input 326 (e.g., non-inverting input) and output 328. First input 324 of A₁ is coupled to first circuit input 304 and second input 326 of A₁ is coupled to first reference input 320.

First stage integrator 106 (1,1) includes switch S₁₁ (also referred to as first switch) which includes first terminal 330 coupled to output 328 of first operational amplifier A₁ and includes second terminal 332. Feedback capacitor C₁ is coupled via switch Sui between output 328 of A₁ and first input 324 of A₁. Feedback capacitor C₁ includes first terminal 334 coupled to first terminal 324 of A₁ and includes second terminal 336 coupled to second terminal 332 of switch S₁₁.

First stage integrator 106 (1,1) includes switch S₁₂ (also referred to as second switch) which includes first terminal 340 coupled to second terminal 336 of feedback capacitor C₁ and includes second terminal 342 coupled to second reference input 322 which is adapted to receive second reference voltage V_{REF2}. First stage integrator 106 (1,1) includes transfer switch S_{T1} which includes first terminal 344 coupled to first input 324 of first operational amplifier A₁ and includes second terminal 346.

The model of sensor 104 (2,1) includes current source I_{S2} which includes first terminal 350 and includes second terminal 352 coupled to common potential 314. In addition, the model of sensor 104 (2,1) includes sensor resistor R_{S2} (e.g., between around 1M ohms to around 1G ohms) which includes first terminal 354 coupled to first terminal 350 of I_{S2} and includes second terminal 356 coupled to common potential 314. Sensor 104 (2,1) is coupled to second circuit input 306 via signal trace T₂ (e.g., conductor, wire, channel and/or printed circuit board trace). Parasitic capacitance C_{PAR_2} may be present between signal trace T₂ and common potential 314. Parasitic capacitance C_{PAR_2} may represent the sum of a sensor parasitic capacitance, a signal trace parasitic capacitance and any other parasitic capacitance.

First stage integrator 106 (2,1) includes second operational amplifier A₂ which includes first input 360 (e.g., inverting input) coupled to second circuit input 306, second input 362 (e.g., non-inverting input) coupled to third reference input 364 and includes output 366. Third reference input 364 is adapted to receive first reference voltage V_{REF1}. First stage integrator 106 (2,1) includes switch S₂₁ (also referred to as third switch) which includes first terminal 368 coupled to output 366 of second operational amplifier A₂ and includes second terminal 370. Feedback capacitor C₂ is coupled between output 366 of A₂ and first input 360 of A₂. Feedback capacitor C₂ includes first terminal 372 coupled to first terminal 360 of A₂ and includes second terminal 374 coupled to second terminal 370 of switch S₂₁.

First stage integrator 106 (2,1) includes switch S₂₂ (also referred to as fourth switch) which includes first terminal 376 coupled to second terminal 374 of feedback capacitor C₂ and includes second terminal 378 coupled to second reference input 380 which is adapted to receive second reference voltage V_{REF2}. First stage integrator 106 (2,1) includes transfer switch S_{T2} which includes first terminal 382 coupled to first input 360 of second operational amplifier A₂ and includes second terminal 384.

Circuit 300 includes second stage integrator 108 (1) which includes third operational amplifier A₃ coupled to first and second operational amplifiers A₁ and A₂ via first and second transfer switches S_{T1} and S_{T2}, respectively. Third operational amplifier A₃ includes first input 386 (e.g., inverting input) coupled to second terminals 346 and 384 of respective transfer switches S_{T1} and S_{T2}. Third operational amplifier A₃ includes second input 388 (e.g., non-inverting input) coupled to fifth reference input 390 which is adapted to receive first reference voltage V_{REF1}. Third operational amplifier A₃ includes output 392, which may be coupled to ADC 112 via multiplexer 110. Feedback capacitor C₃ is coupled between output 392 of A₃ and first input 386 of A₃. Feedback capacitor C₃ includes first terminal 393 coupled to first input 386 of A₃ and includes second terminal 394 coupled to output 392 of A₃. Second stage integrator 108 (1) includes reset switch S_{RST} coupled between first and second terminals 393 and 394 of C₃.

In some example embodiments, circuit 300 includes timing control circuit CTRL (e.g., a processor, logic circuitry, memory, state machine and/or software) configured to provide timing signals to switches S₁₁, S₁₂, S_{T1}, S₂₁, S₂₂ and S_{T2}. Timing control circuit CTRL may include a clock (not shown in FIG. 3) which provides a clock signal. In response, timing control circuit CTRL provides first, second and third timing signals ø1, ø2, ø3 at respective outputs 395, 396 and 397. Timing signal ø1 is applied to control (e.g., to cause the applicable switches to open (cause to be non-conducting) or close (cause to be conducting)) switches S₁₁, S₁₂ and S_{T1}, timing signal ø2 is applied to control switches S₂₁, S₂₂ and S_{T2}, and timing signal ø3 is applied to control switch S_{RST}.

In some example embodiments, circuit 300 is operated in two phases: (1) an integration phase; and (2) a transfer phase. In an integration phase, input current from a sensor (e.g., sensor 104 (1,1)) is received by its corresponding first stage integrator (e.g., first stage integrator 106 (1,1)) and sensor charges that form the input current are integrated over an integration period. In a transfer phase, the first stage integrator (e.g., first stage integrator 106 (1,1)) transfers the resulting integrated charges to a second stage integrator (e.g., second stage integrator 108 (1)) over a transfer period. The second stage integrator (e.g., second stage integrator 108 (1)) provides an output voltage representing the transferred charges.

Similarly, in an integration phase, input current from sensor 104 (2,1) is received by first stage integrator 106 (2,1) which integrates charges that form the input current over an integration period. In a transfer phase, first stage integrator 106 (2,1) transfers the resulting integrated charges to second stage integrator 108 (1) over a transfer period. Second stage integrator 108 (1) provides an output voltage representing the transferred charges.

FIG. 3B illustrates circuit 300 during a first and a second integration phase. During the first integration phase, charges are integrated by first stage integrator 106 (1,1) and during the second integration phase, charges are integrated by first stage integrator 106 (2,1).

During the first integration phase, first timing signal ø1 is asserted LOW (e.g., a logic “0”, a low voltage, such as around ground). In response, switch S₁₁ is closed (e.g., conducting) but switches S₁₂ and S_{T1} are opened (e.g., non-conducting). Thus, output 328 of first operational amplifier A₁ is coupled to first input 324 of A₁ via feedback capacitor C₁, thereby forming a feedback path. Due to the feedback path, first input 324 of A₁ is held at a virtual ground with respect to second input 326 of A₁. Input current I_{S1} from sensor 104 (1,1) flows into feedback capacitor C₁, and charges of I_{S1} are integrated into feedback capacitor C₁ over a first integration period. Because switch S_{T1} remains open during the first integration phase, first stage integrator 106 (1,1) is disconnected from second stage integrator 108 (1).

Similarly, during a second integration phase, second timing ø2 is asserted LOW. In response, switch S₂₁ is closed but switches S₂₂ and S_{T2} are opened. Thus, output 366 of second operational amplifier A₂ is coupled to first input 360 of A₂ via feedback capacitor C₂, thus forming a feedback path. Due to the feedback path, first input 360 of A₂ is held at a virtual ground with respect to second input 362 of A₂. Input current I_{S2} from sensor 104 (2,1) flows into feedback capacitor C₂, and charges of I_{S2} are integrated into feedback capacitor C₂ over a second integration period. Because switch S_{T2} remains open during the second integration phase, first stage integrator 106 (2,1) is disconnected from second stage integrator 108 (1).

In some example embodiments, first and second integration periods may be different in duration and/or starting time. In other example embodiments, first and second integration periods may overlap (at least partially) in time.

FIG. 3C illustrates circuit 300 during a first and a second transfer phase. During the first transfer phase, first timing signal ø1 is asserted HIGH. In response, switch S₁₁ is opened but switches S₁₂ and S_{T1} are closed. Because S₁₁ is opened, output 328 of first operational amplifier A₁ is disconnected from first input 324 of A₁, thus disconnecting the feedback path. Also, because S₂₁ and S_{T1} are both closed, feedback capacitor C₁ is coupled to second reference voltage V_{REF2} and first input 324 of A₁ is coupled to first input 386 of third operational amplifier A₃. As a result, charges integrated into feedback capacitor C₁ are transferred to feedback capacitor C₃ over a first transfer period.

Similarly, during the second transfer phase, second timing signal ø2 is asserted HIGH. In response, switch S₂₁ is opened but switches S₂₂ and S_{T2} are closed. Because S₂₁ is opened, output 366 of second operational amplifier A₂ is disconnected from first input 360 of A₂, thus disconnecting the feedback path. Also, because S₂₂ and S_{T2} are both closed, feedback capacitor C₂ is coupled to second reference voltage V_{REF2} and first input 360 of A₂ is coupled to first input 386 of third operational amplifier A₃. Thus, charges integrated into feedback capacitor C₂ are transferred to feedback capacitor C₃ over a second transfer period.

During the first transfer period, the feedback path formed by feedback capacitor C₁ is disconnected. Thus, during the first transfer period a virtual ground does not exist at first input 324 of first operational amplifier A₁ with respect to second input 326 of A₁, and output voltage V_{O1} is no longer capacitively coupled to first input 324 of A₁. Thus, any noise that may be present at second input 326 of A₁ is not present at first input 324 of A₁ due to the absence of a virtual ground, and any noise that may be present at output 328 of A₁ is not capacitively coupled to first input 324 of A₁. Thus, during the first transfer phase any noise from first input 324 of A₁ or any noise from output 328 of A₁ are not transferred to third operational amplifier A₃. Similarly, during the second transfer phase any noise from first input 360 of A₂ or any noise from output 366 of A₂ are not transferred to third operational amplifier A₃.

In some example embodiments, first and second transfer periods may be different in duration and/or starting time. In other example embodiments, first and second transfer periods may overlap (at least partially) in time.

During the integration phase, first stage integrator 106 (1,1) temporarily stores charges from input current I_{S1} and during the transfer phase, first stage integrator 106 (1,1) transfers the charges to second stage integrator 108 (1). Also, during the transfer phase, first stage integrator 106 (1,1) transfers charges from parasitic capacitor C_{PAR_1} to second stage integrator 108 (1). However, first stage integrator 106 (1,1) does not transfer output voltage V_{O1} to second stage integrator 108 (1). Thus, any noise that may be present at output 328 of A₁ (e.g., noise signals in output voltage V₀₁) is not transferred to second stage integrator 108 (1) and does not degrade the performance of second stage integrator 108 (1). Thus, first operational amplifier A₁ may be implemented as a low-gain, low-bandwidth amplifier which requires fewer gain stages and fewer transistors than required by a high-gain, large-bandwidth amplifier. Similarly, first stage integrator 106 (2,1) may be implemented as a low-gain, low-bandwidth amplifier. Thus, the disclosed embodiments allow implementing A₁ and A₂ as low-gain, low-bandwidth amplifiers, yet not lessening the precision of data acquisition. There are several benefits of using low-gain, low-bandwidth amplifiers instead of using high-gain, large-bandwidth amplifiers. A low-gain, low-bandwidth amplifier consumes considerably less power than a high-gain, large-bandwidth amplifier due to its relaxed noise specifications. Also, because a low-gain, low-bandwidth amplifier has fewer number of transistors, it is less expensive and requires less area to implement in an integrated circuit or a semiconductor die. If a system requires a very large number (e.g., 10K or 100K) of sensors or pixels, thus increasing the number of first stage integrators, these advantages may become considerable.

In some example embodiment, third operational amplifier A₃ may be implemented as a high-gain, large-bandwidth amplifier which has a low noise (also referred to as a precision amplifier). Because A₃ provides output voltage V_{OF} responsive to charges transferred from A₁ and A₂, any noise generated by A₃ may also be transferred to output voltage V_{OF}. Thus, it is beneficial to implement A₃ as a high-gain, large-bandwidth amplifier which has a low noise.

To ensure that output voltage V_{OF} of A₃ is a measure of charges transferred by first stage integrators (e.g., 106 (1,1) and 106 (2,1) of FIG. 3C), feedback capacitor C₃ is reset by switch S_{RST} prior to a transfer period. In some example embodiments, timing signal ø3 is used to control the state of switch S_{RST}. Prior to a transfer period, ø3 is asserted HIGH, which causes S_{RST} to be closed. As such, feedback capacitor C₃ is shorted and is discharged or reset. After C₃ is reset, ø3 is asserted LOW, which causes S_{RST} to be opened. Thus, in the next transfer period, feedback capacitor C₃ is charged only by transferred charges from a first stage integrator, and as such output voltage V_{OF} of A₃ is representative of the transferred charges. In some example embodiments, feedback capacitor C₃ may be reset to a known potential by coupling C₃ to a known reference voltage.

In some example embodiments, after a predetermined duration that is necessary for charges to be transferred from first operational amplifier A₁ to third operational amplifier A₃ or from second operational amplifier A₂ to A₃ and for output voltage V_{OF} to settle, output voltage V_{OF} may be sampled and digitized by an analog-to-digital converter (not illustrated in FIGS. 3A-3C).

In some example embodiments, charges from sensors 104 (1,1)-104 (M,N) may be transferred sequentially in a frame. Thus, for example, charges may be transferred sequentially from the sensors of column number 1, beginning with sensor 104 (1,1). After charges from the last sensor of column number 1 (e.g., sensor 104 (M,1) is transferred, the next frame (e.g., column number 2) may be initiated and the process is repeated.

In some example embodiments, sensors 104 (1,1)-104 (M,N), first stage integrators 106 (1,1)-106 (M,N) and second stage integrators 108 (1)-108 (N) may be implemented in an integrated circuit or a semiconductor die. In some example embodiments, first stage integrators 106 (1,1)-106 (M,N) and second stage integrators 108 (1)-108(N) may be implemented in an integrated circuit which may be coupled to sensors 104 (1,1)-104 (M,N) via an external connection, signal trace, wire, or a conductor. Other variations are possible within the scope of the disclosure.

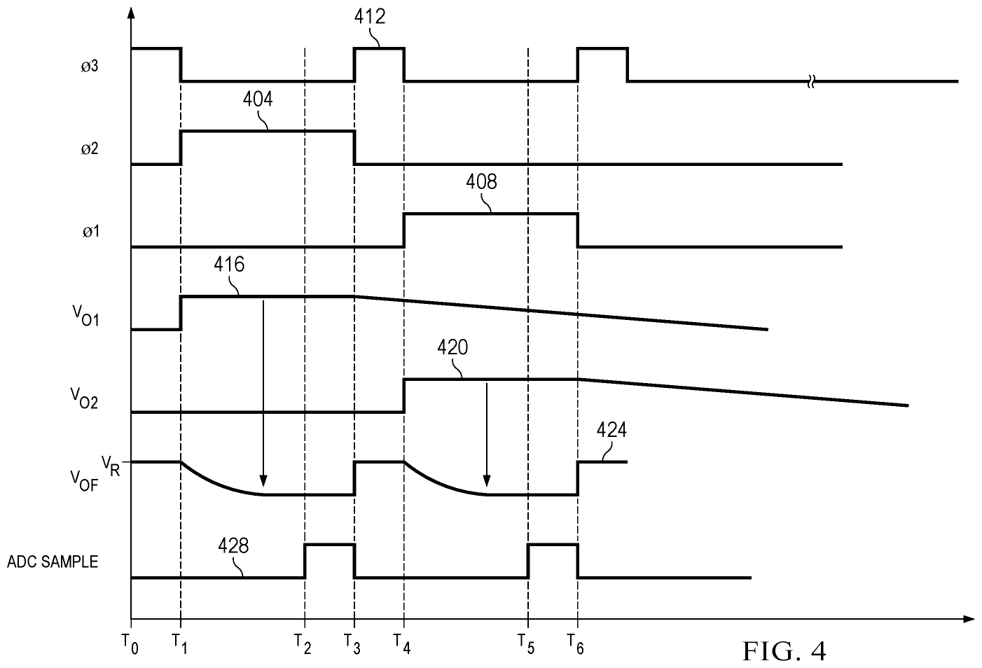

FIG. 4 illustrates timing signals and voltages in circuit 300 of an example embodiment. The x-axis represents time, and the y-axis represents voltage. Initially, at time T0, timing signals ø1 (indicated by reference numeral 404) and ø2 (indicated by reference numeral 408) are LOW and timing signal ø3 (indicated by reference numeral 412) is HIGH. Thus, feedback capacitor C₃ of third operational amplifier A₃ is reset. In some example embodiments, C₃ is reset to a known voltage (e.g., V_{R}). Although at time T0, switches S₁₁ and S₂₁ are closed, output V_{O1} (indicated by reference numeral 416) of operational amplifier A₁ and output V_{O2} (indicated by reference numeral 420) of operational amplifier A₂ are both zero because feedback capacitors C₁ and C₂ are not yet fully charged. At time T0, output V_{OF} (indicated by reference numeral 424) of operational amplifier A₃ is at V_{R} because feedback capacitor C₃ is reset to V_{R}.

At time T₁, ø1 is asserted HIGH. Thus, switch S₁₁ is opened and switches S₂₁ and S_{T1} are closed. As such, C₁ is coupled to second reference voltage V_{REF2}, and first input 324 of first operational amplifier A₁ is coupled to first input 386 of third operational amplifier A₃. Thus, at time T₁, charges from C₁ are transferred to C₃ and output V_{OF} begins to drop. At time T₂, V_{OF} settles and it is sampled (indicated by reference numeral 428) and digitized by an ADC.

At time T3, transfer of charges from C₁ to C₃ is completed, ø1 is asserted LOW and ø3 is asserted HIGH. Thus, C₃ is reset to V_{R} and switch S₁₁ is closed. As such, output voltage V_{OF} rises back to V_{R}.

At time T4, 2 is asserted HIGH. Thus, switches S₂₂ and S_{T2} are closed but switch S₂₁ is opened. Thus, at time T4 transfer of charges from C₂ to C₃ starts. At time T5, output V_{OF} settles and the ADC samples and digitizes V_{OF}. At time T6, transfer of charges from C₂ to C₃ is completed and ø2 is asserted LOW. Thus, V_{OF} rises back to VR.

The circuits described herein may include one or more semiconductor elements (such as transistors), one or more passive elements (such as resistors, capacitors and/or inductors), and/or one or more sources (such as voltage and/or current sources). The circuits may include only semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party. While some example embodiments may include certain elements implemented in an integrated circuit and other elements are external to the integrated circuit, in other example embodiments, additional or fewer features may be incorporated into the integrated circuit. In addition, some or all the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, the term “couple” may cover connections, communications, or signal paths that enable a functional relationship consistent with this description. For example, if device A provides a signal to control device B to perform an action, then: (a) in a first example, device A is coupled to device B; or (b) in a second example, device A is coupled to device B through intervening component C if intervening component C does not substantially alter the functional relationship between device A and device B, such that device B is controlled by device A via the control signal provided by device A. Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, in this description, a circuit or device that includes certain components may instead be adapted to be coupled to those components to form the described circuitry or device. For example, a structure described as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party.

As used herein, the terms “terminal”, “node”, “interconnection” and “pin” are used interchangeably. Unless specifically stated to the contrary, these terms are generally used to mean an interconnection between or a terminus of a device element, a circuit element, an integrated circuit, device or other electronics or semiconductor component.

While some example embodiments suggest that certain elements are included in an integrated circuit while other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g., NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

While certain components may be described herein as being of a particular process technology, these components may be exchanged for components of other process technologies. Circuits described herein are reconfigurable to include the replaced components to provide functionality at least partially similar to functionality available before the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor. Also, uses of the phrase “ground terminal” in this description include a chassis ground, an Earth ground, a floating ground, a virtual ground, a digital ground, a common ground, and/or any other form of ground connection applicable to, or suitable for, the teachings of this description. Unless otherwise stated, “about”, “approximately”, or “substantially” preceding a value means +/−10 percent of the stated value, or, if the value is zero, a reasonable range of values around zero.

What is claimed is:

1. A circuit having a plurality of circuit inputs, at least one of the plurality of circuit inputs adapted to receive an input current, the circuit having a first reference input adapted to receive a first reference voltage and having a second reference input adapted to receive a second reference voltage, the circuit comprising:
a plurality of first stage integrators, each of the plurality of first stage integrators including a first input, a second input, a third input and an output, the first input of each of the plurality of first stage integrators coupled to a different one of the circuit inputs, the second input coupled to the first reference input, the third input coupled to the second reference input and the output of each of the plurality of first stage integrators coupled to the first input of such first stage integrator by a first feedback path for such first stage integrator; and
a second stage integrator including a first input, a second input and an output, the first input of the second stage integrator coupled to each of the first inputs of the plurality of first stage integrators, the second input of the second stage integrator coupled to the first reference input, and the output of the second stage integrator coupled to the first input of the second stage integrator by a second feedback path.

2. The circuit of claim 1, further comprising a plurality of transfer switches, each of the plurality of transfer switches including a first terminal and a second terminal, the first terminal of each of the plurality of transfer switches coupled to a different one of the first inputs of the plurality of first stage integrators and the second terminal of each of the plurality of transfer switches coupled to the first input of the second stage integrator.

3. The circuit of claim 1, wherein the first feedback path comprises:
a first switch including a first terminal coupled to the output of the first stage integrator and including a second terminal; and
a first feedback capacitor including a first terminal coupled to the first input of the first stage integrator and a second terminal coupled to the second terminal of the first switch.

4. The circuit of claim 3, wherein each of the plurality of first stage integrators further comprises a second switch including a first terminal coupled to the second terminal of the first feedback capacitor of such first stage integrator and a second terminal adapted to receive the second reference voltage.

5. The circuit of claim 1, wherein each of the plurality of first stage integrators further comprises a transfer switch including a first terminal coupled to the first input of such first stage integrator and a second terminal coupled to the first input of the second stage integrator.

6. The circuit of claim 1, wherein the second feedback path includes a second feedback capacitor including a first terminal coupled to the first input of the second stage integrator and a second terminal coupled to the output of the second stage integrator.

7. The circuit of claim 1, wherein the second stage integrator comprises a reset switch including a first terminal coupled to the first input of the second stage integrator and a second terminal coupled to the output of the second stage integrator.

8. The circuit of claim 7, wherein the reset switch is configured to reset the second feedback capacitor.

9. A circuit having a circuit input adapted to receive an input current, the circuit having a first reference input adapted to receive a first reference voltage and having a second reference input adapted to receive a second reference voltage, the circuit comprising:
a first stage integrator including a first input coupled to the circuit input, a second input coupled to the first reference input, a third input coupled to the second reference input and an output coupled to the first input of the first stage integrator via a first feedback path;
a transfer switch including a first terminal coupled to the first input of the first stage integrator and including a second terminal; and
a second stage integrator including a first input coupled to the second terminal of the transfer switch, a second input coupled to the first reference input, and an output coupled to the first input of the second stage integrator by a third feedback path.

10. The circuit of claim 9, wherein the first feedback path comprises:
a first switch including a first terminal coupled to the output of the first stage integrator and including a second terminal; and
a first feedback capacitor including a first terminal coupled to the first input of the first stage integrator and a second terminal coupled to the second terminal of the first switch.

11. The circuit of claim 9, wherein the second feedback path includes a second feedback capacitor including a first terminal coupled to the first input of the second stage integrator and a second terminal coupled to the output of the second stage integrator.

12. The circuit of claim 9, wherein the second stage integrator comprises a reset switch including a first terminal coupled to the first input of the second stage integrator and a second terminal coupled to the output of the second stage integrator.

13. A circuit having a circuit input adapted to receive an input current, the circuit having a first reference input adapted to receive a first reference voltage and having a second reference input adapted to receive a second reference voltage, the circuit comprising:
a first amplifier including a first input coupled to the circuit input, a second input coupled to the first reference input and including an output;
a first switch including a first terminal coupled to the output of the first amplifier and including a second terminal;
a first feedback capacitor including a first terminal coupled to the first input of the first amplifier and a second terminal coupled to the second terminal of the first switch;
a second switch including a first terminal coupled to the second terminal of the first feedback capacitor and a second terminal coupled to the second reference input;
a transfer switch including a first terminal coupled to the first input of the first amplifier and including a second terminal;
a second amplifier including a first input coupled to the second terminal of the transfer switch, a second input coupled to the first reference input and including an output; and
a second feedback capacitor including a first terminal coupled to the first input of the second amplifier and a second terminal coupled to the output of the second amplifier.

14. The circuit of claim 13, further comprising a reset switch including a first terminal coupled to the first terminal of the second feedback capacitor and a second terminal coupled to the second terminal of the second feedback capacitor.

15. A circuit having a plurality of circuit inputs, at least one of the plurality of circuit inputs adapted to receive an input current, the circuit having a first reference input adapted to receive a first reference voltage and having a second reference input adapted to receive a second reference voltage, the circuit comprising:
a plurality of first stage integrators, wherein each first stage integrator of the plurality of first stage integrators includes a first input coupled to a different one of the circuit inputs, a second input coupled to the first reference input, a third input coupled to the second reference input and an output coupled to the first input of such first stage integrator by a first feedback path; and
a second stage integrator including a first input coupled to the first inputs of each of the plurality of first stage integrators, a second input coupled to the first reference input, and an output coupled to the first input of the second stage integrator by a second feedback path.

16. The circuit of claim 15, wherein each of the plurality of first stage integrators further comprises a transfer switch including a first terminal coupled to the first input of such first stage integrator and a second terminal coupled to the first input of the second stage integrator.

17. The circuit of claim 15, further comprising a reset switch including a first terminal coupled to the first terminal of the second stage integrator and a second terminal coupled to the output of the second stage integrator.
